(19) United States
(12) Patent Application Publication
(10) Pub. No.: US 2025/0393259 A1
(43) Pub. Date: Dec. 25, 2025

(54) TRANSISTOR AND METHOD FOR MANUFACTURING SAME

(71) Applicant: Microchip Technology Incorporated, Chandler, AZ (US)

(72) Inventors: Shesh Mani Pandey, Gilbert, AZ (US); Sundar Babu Isukapati, Gilbert, AZ (US); George Dorman, Chandler, AZ (US); Kevin Speer, Bentonville, AR (US)

(73) Assignee: Microchip Technology Incorporated, Chandler, AZ (US)

(21) Appl. No.: 18/975,450

(22) Filed: Dec. 10, 2024

Related U.S. Application Data
(60) Provisional application No. 63/662,897, filed on Jun. 21, 2024.

(51) Int. Cl. H10D 30/83; H10D 30/01

(52) U.S. Cl. CPC H10D 30/831; H10D 30/0515

(57) ABSTRACT

A transistor that may include a drift layer formed on a substrate. A well implant layer formed within the drift layer wherein the well implant layer has a first gap. A gate implant layer formed within the drift layer and partially over the well implant layer wherein the gate implant layer has a second gap. A source implant layer formed within the drift layer and within the second gap of the gate implant layer. A plurality of gate contacts operatively connected to the gate implant layer. A source contact operatively connected to the source implant layer.

### CROSS-REFERENCE TO RELATED APPLICATION

The present application claims priority to U.S. Provisional Patent Application No. 63/662,897, filed on Jun. 21, 2024, the contents of which are hereby incorporated by reference in their entirety.

### TECHNICAL FIELD

The present disclosure relates generally to transistors, and more specifically to Junction Field Effect Transistors (JFETs) and methods for manufacturing same to improve the performance of the transistor.

### SUMMARY

According to an aspect of one or more examples, there is provided a transistor that may include a substrate, a drift layer formed on the substrate, a well implant layer formed within the drift layer, the well implant layer having a first gap, a gate implant layer formed within the drift layer and partially over the well implant layer, the gate implant layer having a second gap, a source implant layer formed within the drift layer and within the second gap of the gate implant layer, a plurality of gate contacts operatively connected to the gate implant layer, and a source contact operatively connected to the source implant layer. The transistor may comprise a planar surface formed over the source implant layer and the gate implant layer. The planar surface may comprise an insulating layer. The substrate may comprise a first concentration of a first type dopant. The drift layer may comprise a second concentration of the first type dopant. The second concentration may be greater than the first concentration. The well implant layer may comprise a third concentration of a second type dopant. The gate implant layer may comprise a fourth concentration of the second type dopant. The fourth concentration may be greater than the third concentration. The source implant layer may comprise a fifth concentration of the first type dopant. The fifth concentration may be greater than the first concentration. The first type dopant may comprise an n-type dopant and the second type dopant may comprise a p-type dopant. The first type dopant may comprise a p-type dopant and the second type dopant may comprise an n-type dopant.

According to an aspect of one or more examples, there is provided method of manufacturing a transistor. The method may include providing a substrate, forming a drift layer on the substrate, forming a well implant layer within the drift layer, the well implant layer having a first gap, forming a gate implant layer within the drift layer and partially over the well implant layer, the gate implant layer having a second gap, forming a source implant layer within the drift layer and within the second gap of the gate implant layer, forming a plurality of gate contacts operatively connected to the gate implant layer, and forming a source contact operatively connected to the source implant layer. The method may comprise forming a planar surface over the source implant layer and the gate implant layer. The planar surface may comprise an insulating layer. The substrate may comprise a first concentration of a first type dopant. The drift layer may comprise a second concentration of the first type dopant. The second concentration may be greater than the first concentration. The well implant layer may comprise a third concentration of a second type dopant. The gate implant layer may comprise a fourth concentration of the second type dopant. The fourth concentration may be greater than the third concentration. The source implant layer may comprise a fifth concentration of the first type dopant. The fifth concentration may be greater than the first concentration. The first type dopant may comprise an n-type dopant and the second type dopant may comprise a p-type dopant. The first type dopant may comprise a p-type dopant and the second type dopant may comprise an n-type dopant.

### BRIEF DESCRIPTION OF DRAWINGS

FIG. 1 shows an illustration of a transistor according to one or more examples.

FIG. 2A is a cross sectional view of some of the steps in a method of manufacturing a transistor according to one or more examples.

FIG. 2B is a cross sectional view of some of the steps in a method of manufacturing a transistor according to one or more examples.

FIG. 2C is a cross sectional view of some of the steps in a method of manufacturing a transistor according to one or more examples.

FIG. 2D is a cross sectional view of some of the steps in a method of manufacturing a transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

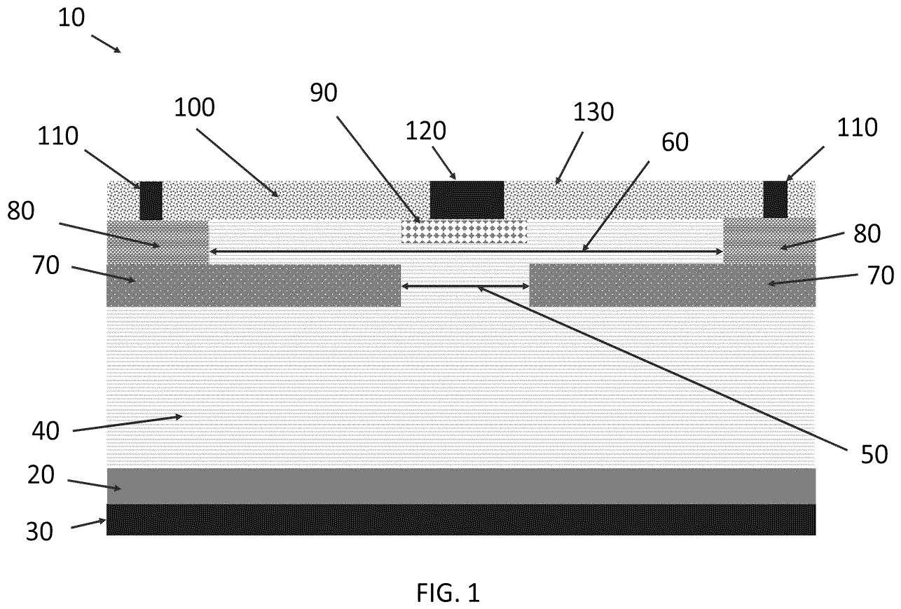

FIG. 1 shows an illustration of a transistor according to one or more examples. Transistor 10 may represent, and may be called a JFET, without limitation. The example transistor 10 (JFET) of FIG. 1 may include a substrate 20. The substrate 20 shown in FIG. 1 may have a first concentration of a first type dopant, e.g., 5E18 (i.e. 5×10¹⁸). The example transistor 10 (JFET) of FIG. 1 may include a drift layer 40 that may be formed within the substrate 20 at one side of the substrate 20 by creating a more heavily doped portion of the first type dopant (higher second concentration of first type dopant, e.g., a concentration of greater than 5E18) of the substrate 20. The example transistor 10 (JFET) of FIG. 1 may also include a drain contact 30 formed at a first side of the substrate 20, the first side of the substrate 20 is opposite the second side of the substrate 20 where the drift layer 40 is formed. The drain contact 30 may be made from a metal, polysilicon, or other suitable material. The example transistor 10 (JFET) of FIG. 1 may include a well implant layer 70 formed within the drift layer 40. The well implant layer 70 may have a first gap 50 that is a space that separates the well implant layer 70 into at least two portions. The well implant layer 70 may comprise a third concentration of a second type dopant that may have a peak doping in the range 1E17 to 5E18. The example transistor 10 (JFET) of FIG. 1 may include a gate implant layer 80 formed within the drift layer 40 and formed partially over the well implant layer 70. The gate implant layer 80 may have a second gap 60 that is a space that separates the gate implant layer 80 into at least two portions. The gate implant layer 80 may comprise a fourth concentration of the second type dopant that may have a peak doping in the range 5E18 to 1E19 with a surface doping in the range 5E16 to 5E17 (the fourth concentration of the second type dopant is higher than the third concentration of the second type dopant). The example transistor 10 (JFET) of FIG. 1 may include a plurality of gate contacts 110 operatively connected to the gate implant layer 80. The gate contacts 110 may be made from a metal, polysilicon, or other suitable material. The example transistor 10 (JFET) of FIG. 1 may include a source implant layer 90 having a fifth concentration of the first type dopant (the fifth concentration of first type dopant is greater than the first concentration of first type dopant). The source implant layer 90 may be formed within the drift layer 40 and formed within the second gap 60 of the gate implant layer 80. The example transistor 10 (JFET) of FIG. 1 may include a source contact 120 operatively connected to the source implant layer 90. The source contact 120 may be made from a metal, polysilicon, or other suitable material. The example transistor 10 (JFET) of FIG. 1 may include a planar surface 130. The planar surface 130 may include an insulating layer 100 that is over the drift layer 40, over the gate layer 80 and over the source layer 90. The insulating layer 100 may comprise polysilicon, silicon dioxide or a mixture of polysilicon and silicon dioxide. When a gate-to-source voltage is applied to the transistor 10 (JFET) of FIG. 1, current flows through a channel created within the second gap 60 and the first gap 50 from the source contact 120 to the drain layer 30.

In the example transistor 10 (JFET) of FIG. 1, the first type dopant may be an n-type dopant with the second type dopant being a p-type dopant. Alternatively, the first type dopant may be a p-type dopant with the second type dopant being an n-type dopant.

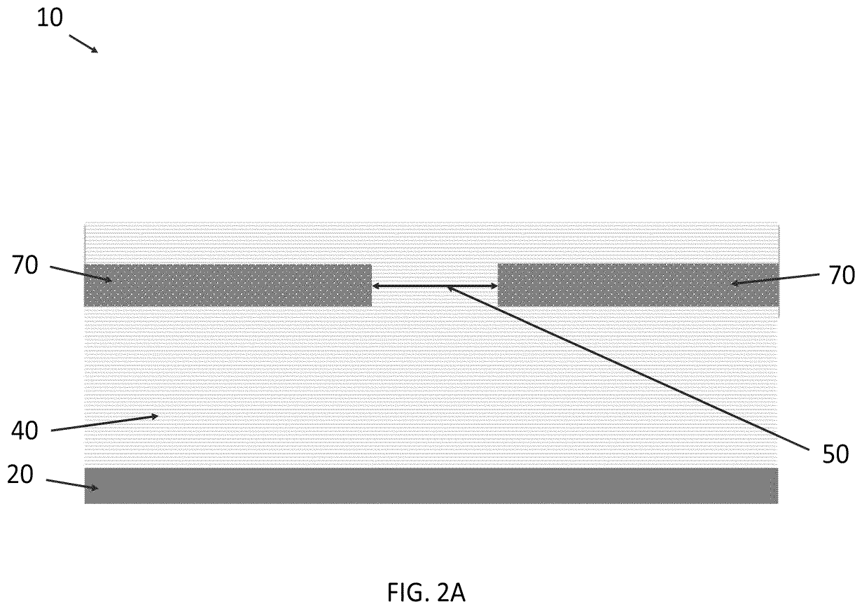

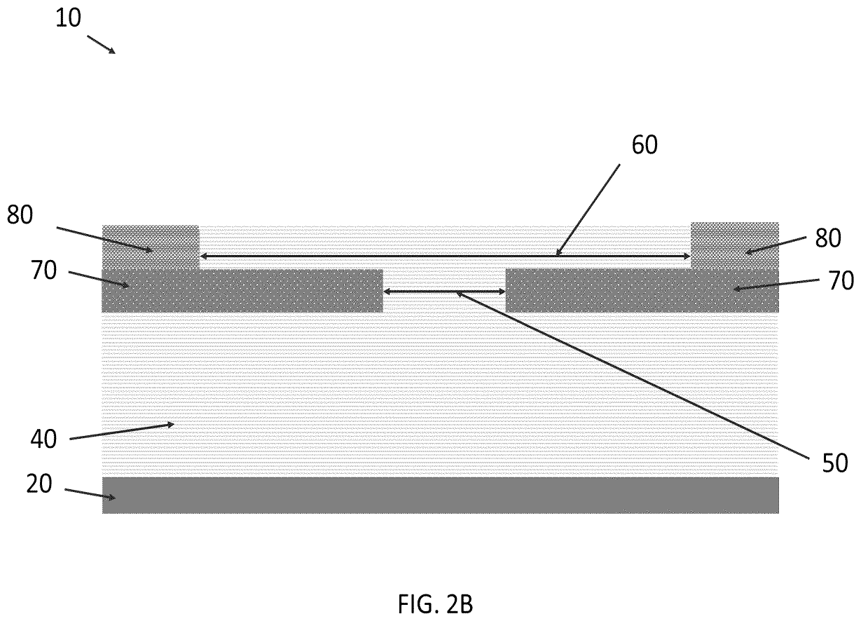

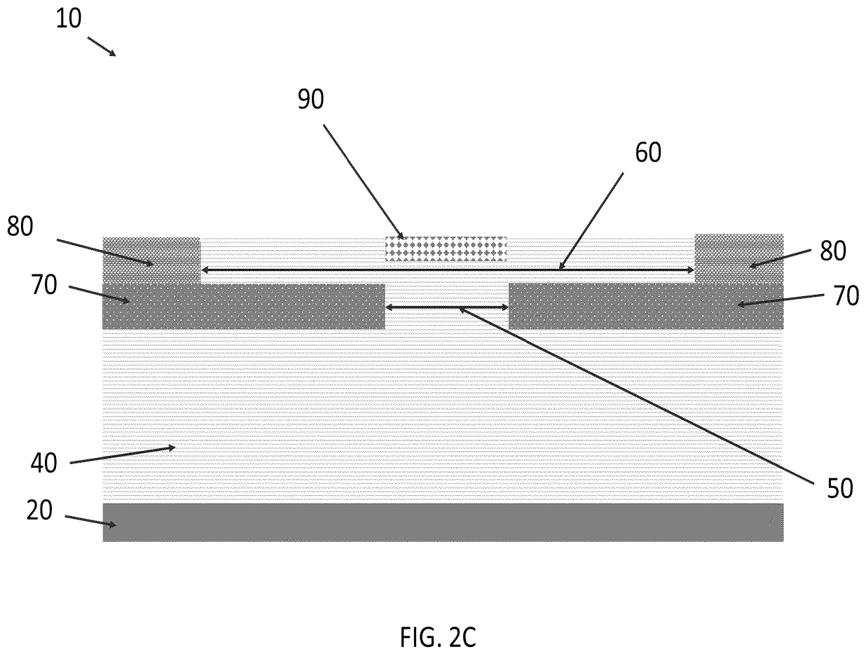

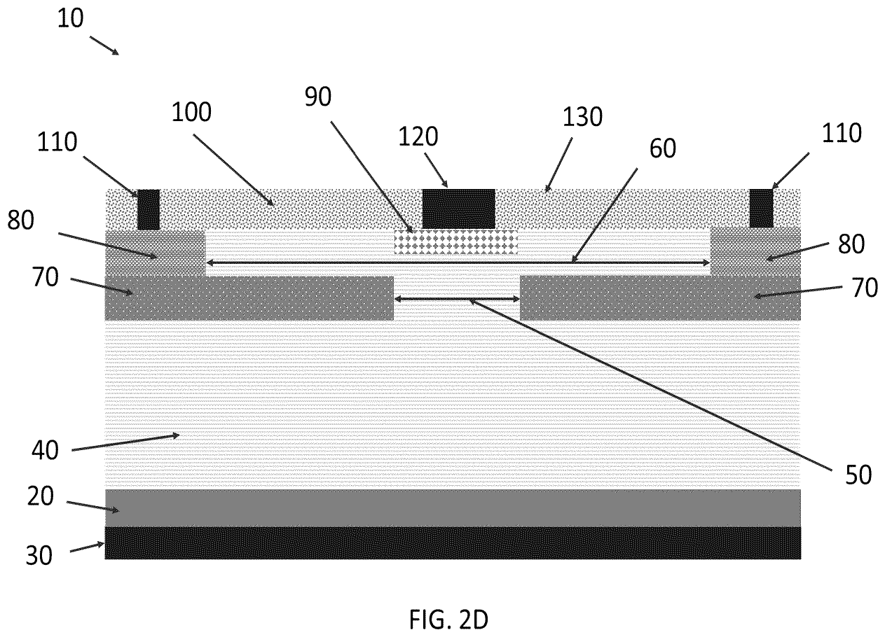

FIGS. 2A-2D show a method of manufacturing transistor 10 (JFET) according to one or more examples. Although the example method shown in FIGS. 2A-2D include steps shown in a particular order, the steps may be performed in a different order, and may include additional steps that are not explicitly shown.

FIG. 2A is a cross sectional view of some of the steps in a method of manufacturing a transistor 10 (JFET) according to one or more examples. In FIG. 2A, the example method shows a substrate 20 that may have a first concentration of a first type dopant, e.g., 5E18 (i.e. 5×10¹⁸). In FIG. 2A, the method may include forming a drift layer 40 that may be formed at one side of the substrate 20 by creating a more heavily doped portion of the first type dopant (higher second concentration of first type dopant, e.g., a concentration of greater than 5E18) of the substrate 20. In FIG. 2A, the method may include forming a well implant layer 70 within the drift layer 40. The well implant layer 70 may have a first gap 50 that is a space that separates the well implant layer 70 into at least two portions. The well implant layer 70 may comprise a third concentration of a second type dopant that may have a peak doping in the range 1E17 to 5E18.

FIG. 2B is a cross sectional view of some of the steps in a method of manufacturing a transistor 10 (JFET) according to one or more examples. FIG. 2B includes forming a gate implant layer 80 within the drift layer 40 and formed partially over the well implant layer 70. The gate implant layer 80 may have a second gap 60 that is a space that separates the gate implant layer 80 into at least two portions. The gate implant layer 80 may comprise a fourth concentration of the second type dopant that may have a peak doping in the range 5E18 to 1E19 with a surface doping in the range 5E16 to 5E17 (the fourth concentration of the second type dopant is higher than the third concentration of the second type dopant).

FIG. 2C is a cross sectional view of some of the steps in a method of manufacturing a transistor 10 (JFET) according to one or more examples. In the method step shown in FIG. 2C, the method may include forming a source implant layer 90 having a fifth concentration of the first type dopant (the fifth concentration of first type dopant is greater than the first concentration of first type dopant). The source implant layer 90 may be formed within the drift layer 40 and formed within the second gap 60 of the gate implant layer 80.

FIG. 2D is a cross sectional view of some of the steps in a method of manufacturing a transistor 10 (JFET) according to one or more examples. In FIG. 2D, the method may include forming a plurality of gate contacts 110 operatively connected to the gate implant layer 80. The gate contacts may be made from a metal, polysilicon, or other suitable material. In FIG. 2D, the method may include forming a source contact 120 operatively connected to the source implant layer 90. The source contact may be made from a metal, polysilicon, or other suitable material. In FIG. 2D, the method may include forming a drain contact 30 at a first side of the substrate 20, the first side of the substrate 20 is opposite the second side of the substrate 20 where the drift layer 40 is formed. The drain contact 30 may be made from a metal, polysilicon, or other suitable material. In FIG. 2D, the method may include forming a planar surface 130. The planar surface 130 may include forming an insulating layer 100 that may be formed over the drift layer 40, formed over the gate layer 80 and formed over the source layer 90. The insulating layer 100 may comprise polysilicon, silicon dioxide or a mixture of polysilicon and silicon dioxide. When a gate-to-source voltage is applied to the transistor 10 (JFET) of FIG. 2D, current flows through a channel created within the second gap 60 and the first gap 50 from the source contact 120 to the drain layer 30.

The example method of manufacturing transistor 10 (JFET) of FIGS. 2A-2D may have the first type dopant be an n-type dopant with the second type dopant being a p-type dopant. Alternatively, the first type dopant may be a p-type dopant with the second type dopant being an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A transistor comprising:
a substrate;
a drift layer formed on the substrate;
a well implant layer formed within the drift layer, the well implant layer having a first gap;
a gate implant layer formed within the drift layer and partially over the well implant layer, the gate implant layer having a second gap;
a source implant layer formed within the drift layer and within the second gap of the gate implant layer;
a plurality of gate contacts operatively connected to the gate implant layer; and
a source contact operatively connected to the source implant layer.

2. The transistor of claim 1 comprises a planar surface formed over the source implant layer and the gate implant layer.

3. The transistor of claim 2 wherein the planar surface comprises an insulating layer.

4. The transistor of claim 1, wherein the substrate comprises a first concentration of a first type dopant.

5. The transistor of claim 4, wherein the drift layer comprises a second concentration of the first type dopant.

6. The transistor of claim 5, wherein the well implant layer comprises a third concentration of a second type dopant.

7. The transistor of claim 6, wherein the gate implant layer comprises a fourth concentration of the second type dopant, the fourth concentration is greater than the third concentration.

8. The transistor of claim 7, wherein the source implant layer comprises a fifth concentration of the first type dopant.

9. The transistor of claim 8, wherein the first type dopant comprises an n-type dopant and the second type dopant comprises a p-type dopant.

10. The transistor of claim 8, wherein the first type dopant comprises a p-type dopant and the second type dopant comprises an n-type dopant.

11. A method of manufacturing a transistor, the method comprising:
providing a substrate;
forming a drift layer on the substrate;
forming a well implant layer within the drift layer, the well implant layer having a first gap;
forming a gate implant layer within the drift layer and partially over the well implant layer, the gate implant layer having a second gap;
forming a source implant layer within the drift layer and within the second gap of the gate implant layer;
forming a plurality of gate contacts operatively connected to the gate implant layer; and
forming a source contact operatively connected to the source implant layer.

12. The method of claim 11 comprises forming a planar surface over the source implant layer and the gate implant layer.

13. The method of claim 12 wherein the planar surface comprises an insulating layer.

14. The method of claim 11, wherein the substrate comprises a first concentration of a first type dopant.

15. The method of claim 14, wherein the drift layer comprises a second concentration of the first type dopant.

16. The method of claim 15, wherein the well implant layer comprises a third concentration of a second type dopant.

17. The method of claim 16, wherein the gate implant layer comprises a fourth concentration of the second type dopant, the fourth concentration is greater than the third concentration.

18. The method of claim 17, wherein the source implant layer comprises a fifth concentration of the first type dopant.

19. The method of claim 18, wherein the first type dopant comprises an n-type dopant and the second type dopant comprises a p-type dopant.

20. The method of claim 18, wherein the first type dopant comprises a p-type dopant and the second type dopant comprises an n-type dopant.
